(19) United States
(12) Patent Application Publication
(10) Pub. No.: US 2026/0059874 A1
(43) Pub. Date: Feb. 26, 2026

(54) IMAGE SENSOR

(71) Applicant: Samsung Electronics Co., Ltd., Suwon-si (KR)

(72) Inventors: JUNGWOOK LIM, Suwon-si (KR); YOUNGGU JIN, Suwon-si (KR); Jooho Hwang, Suwon-si (KR)

(21) Appl. No.: 19/231,503

(22) Filed: Jun. 8, 2025

(30) Foreign Application Priority Data
Aug. 26, 2024 (KR) 10-2024-0114594

(51) Int. Cl. H10F 39/18; H10F 39/00

(52) U.S. Cl. CPC H10F 39/1865; H10F 39/8037; H10F 39/807; H10F 39/809; H10F 39/811

(57) ABSTRACT

An image sensor includes a pixel array including pixel units and a readout circuit configured to receive a pixel signal from each of the pixel units. Each of the pixel units includes a plurality of sub-pixels separated by a deep trench isolation (DTI) structure, a plurality of floating diffusion regions, and a lateral overflow integration capacitor in which overflowed charges are accumulated, and each of the sub-pixels includes a photodiode. One of the plurality of floating diffusion regions may include partial floating diffusion regions in at least two of the plurality of sub-pixels, and the partial floating diffusion regions have the same potential. One of the plurality of sub-pixels may include a drain region connected to a power supply voltage node, a first transistor adjacent to the drain region, and a doped region between the photodiode and the drain region and doped with an N-type dopant.

### CROSS-REFERENCE TO RELATED APPLICATION(S)

This U.S. non-provisional application claims priority under 35 U.S. C. § 119 to Korean Patent Application No. 10-2024-0114594, filed on Aug. 26, 2024, in the Korean Intellectual Property Office, the disclosure of which is herein incorporated by reference in its entirety.

### BACKGROUND

Example embodiments relate to an image sensor and, more particularly, to an image sensor for preventing blooming.

Image sensors convert optical signals into electrical signals, and include charge-coupled device (CCD) image sensors and complementary metal-oxide semiconductor (CMOS) image sensors.

Among CMOS image sensors, an active pixel sensor (APS) transfers charges, generated by an optical signal incident on a photodiode (PD), to a floating diffusion region, and a drive transistor converts a potential of the floating diffusion region into a voltage, which is then output to a column line.

Image sensors are continually being developed with a focus on improving dynamic ranges to enhance image quality.

### SUMMARY

Example embodiments provide an image sensor configured to prevent photocharges from moving through an unintended path.

According to an example embodiment, an image sensor includes a first photoelectric conversion device disposed in a first region of a pixel unit and a second photoelectric conversion device disposed in a second region of the pixel unit, a deep trench isolation (DTI) structure disposed between the first photoelectric conversion device and the second photoelectric conversion device, a plurality of floating diffusion regions storing charges transferred from at least one of the first photoelectric conversion device and the second photoelectric conversion device, a lateral overflow integration capacitor configured to store charges overflowed from the second photoelectric conversion device, a drain region connected to a power supply voltage node and disposed in the first region, a first transistor disposed in the first region and adjacent to the drain region, and a first doped region disposed between the first photoelectric conversion device and the drain region and doped with an N-type dopant. One of the plurality of floating diffusion regions may include partial floating diffusion regions, and the partial floating diffusion regions may be electrically connected to each other with the DTI structure interposed therebetween, and may be disposed in the first region and the second region, respectively.

According to an example embodiment, an image sensor includes a pixel array including a plurality of pixel units and a readout circuit configured to receive a pixel signal from each of the plurality of pixel units. Each of the plurality of pixel units may include a plurality of sub-pixels separated by a deep trench isolation (DTI) structure, a plurality of floating diffusion regions, and a lateral overflow integration capacitor in which overflowed charges are accumulated, and each of the plurality of sub-pixels may include a photoelectric conversion device. One of the plurality of floating diffusion regions may include partial floating diffusion regions disposed in at least two sub-pixels among the plurality of sub-pixels, and the partial floating diffusion regions may have the same potential. One of the plurality of sub-pixels may include a drain region connected to a power supply voltage node, a first transistor adjacent to the drain region, and a doped region disposed between the photoelectric conversion device and the drain region within a substrate and doped with an N-type dopant.

According to an example embodiment, an image sensor includes a first region in which a first photoelectric conversion device having a first area is disposed, a second region in which a second photoelectric conversion device having a second area, smaller than the first area, is disposed, a deep trench isolation (DTI) structure separating the first region and the second region, a first floating diffusion region connected to the first photoelectric conversion device through a first transfer transistor, a second floating diffusion region connected to the second photoelectric conversion device through a second transfer transistor, a third floating diffusion region selectively electrically coupled to at least one of the first and second floating diffusion regions, a lateral overflow integration capacitor in which charges, overflowed from the second photoelectric conversion device, are accumulated, a drain region connected to a power supply voltage node and disposed in the first region, a first transistor disposed in the first region and adjacent to the drain region, and a doped region disposed between the first photoelectric conversion device and the drain region within a substrate and doped with an N-type dopant. One of the first, second, and third floating diffusion regions may include partial floating diffusion regions, respectively disposed in the first region and the second region, and the partial floating diffusion regions may have the same potential.

### BRIEF DESCRIPTION OF DRAWINGS

FIG. 1 is a block diagram of an image sensor according to an example embodiment.

FIG. 2 is a conceptual plan view of a pixel unit according to an example embodiment.

FIG. 3 is a conceptual cross-sectional view of the pixel unit of FIG. 2.

FIG. 4 is a circuit diagram illustrating a pixel unit of an image sensor according to an example embodiment.

FIGS. 5 to 7 are conceptual plan views of pixel units according to example embodiments, respectively.

FIG. 8 is a diagram illustrating an example of a pixel unit layout based on a circuit diagram of the pixel unit of FIG. 4.

FIG. 9 is a simplified plan view illustrating an example of the layout of the pixel unit of FIG. 8.

FIG. 10 is a diagram illustrating a conceptual example of a cross-section taken along A-A′ in the layout of the pixel of FIG. 9.

FIG. 11 is a diagram illustrating an example of a cross-section taken along B-B′ in a cross-sectional view of the pixel in FIG. 10.

FIG. 12 is a diagram illustrating an example of a cross-section taken along A-A′ in the layout of the pixel of FIG. 9.

FIG. 13 is a diagram illustrating an example of a pixel unit layout based on the circuit diagram of the pixel unit of FIG. 4.

FIG. 14 is a simplified plan view illustrating an example of the layout of the pixel unit of FIG. 13.

FIG. 15 is a circuit diagram illustrating a pixel unit of an image sensor according to an example embodiment.

FIG. 16 is a diagram illustrating an example of a pixel unit layout based on the circuit diagram of the pixel unit of FIG. 15.

FIG. 17 is a circuit diagram illustrating a pixel unit of an image sensor according to an example embodiment.

FIG. 18 is a diagram illustrating an image sensor according to an example embodiment.

FIG. 19 is a diagram illustrating an image sensor according to an example embodiment.

FIG. 20 is a diagram illustrating an image sensor according to an example embodiment.

### DETAILED DESCRIPTION

Hereinafter, example embodiments will be described with reference to the accompanying drawings. Like reference characters refer to like elements throughout. Terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to emphasize this meaning, unless the context or other statements indicate otherwise.

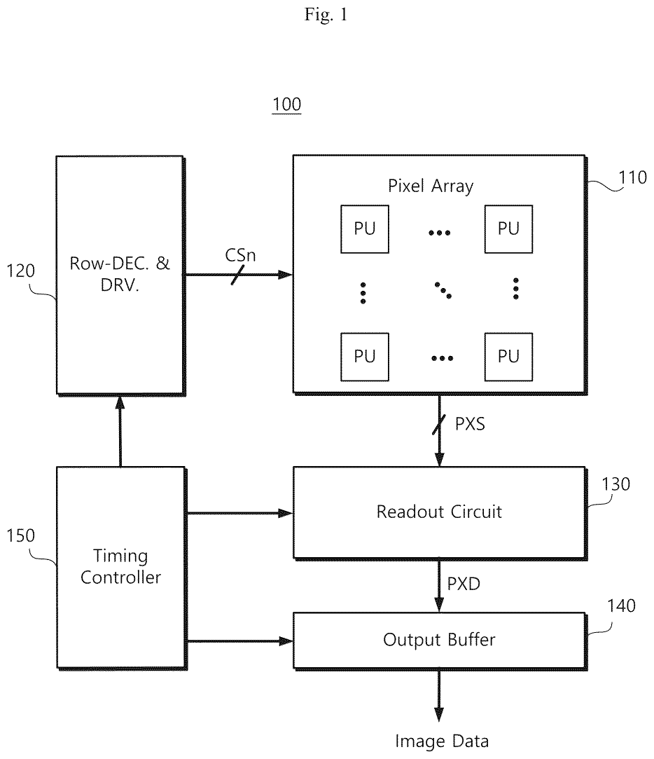

FIG. 1 is a block diagram of an image sensor according to an example embodiment.

Referring to FIG. 1, an image sensor 100 may include a pixel array 110, a row decoder/driver 120, a readout circuit 130, an output buffer 140, and a timing controller 150.

The pixel array 110 may include a plurality of pixel units PU. For example, the pixel units PU may be arranged in a matrix. Each of the pixel units PU may include a plurality of sub-pixels. A pixel or pixel unit refers to a sensor element of an image sensor.

The pixel array 110 may receive a plurality of pixel control signals CSn, such as a select signal, a reset control signal, a transfer control signal, a gain control signal, a switch control signal, or a voltage select signal, from the row decoder/driver 120. The pixel control signals CSn may control the pixel unit PU and/or sub-pixels of the pixel unit PU.

The pixel array 110 may operate under the control of the received pixel control signals CSn, and each of the pixel units PU and/or sub-pixels may convert an optical signal into an electrical signal. An electrical signal, generated by each of the pixel units PU and/or sub-pixels, may be provided to the readout circuit 130 through a plurality of column lines. For example, a pixel signal PXS generated by each of the pixel units PU and/or sub-pixels may be provided to the readout circuit 130 through a corresponding column line among the plurality of column lines. In an example embodiment, the pixel signal PXS may be an image pixel signal corresponding to a photocharge generated in the pixel units PU and/or sub-pixels. Alternatively, the pixel signal PXS may be a reset pixel signal corresponding to a voltage level of a reset floating diffusion region.

Each of the pixel units PU may include at least two sub-pixels. Each of the sub-pixels may include a photoelectric device. For example, each of the pixel units PU may include two sub-pixels, and each of the two sub-pixels may include an additional photoelectric device.

In an example embodiment, when viewed in a direction perpendicular to a substrate, areas occupied by sub-pixels included in the same pixel unit PU may be different from each other. For example, one sub-pixel may have a larger light-receiving area than another sub-pixel. A photoelectric device of one sub-pixel may have a larger light-receiving area than a photoelectric device of another sub-pixel. The photoelectric device having a relatively large light-receiving area may be referred to as a large photodiode LPD, and the photoelectric device having a relatively small light-receiving area may be referred to as a small photodiode SPD.

In an example embodiment, when viewed in a direction perpendicular to the substrate, areas occupied by sub-pixels included in the same pixel unit PU may be the same. For example, photoelectric devices included in each of the sub-pixels may have the same light-receiving area. Sub-pixels included in the same pixel unit PU may include color filters corresponding to the same color channel. Alternatively, a portion of the sub-pixels included in the same pixel unit PU may include color filters corresponding to different color channels.

In an example embodiment, the photoelectric device may be a photodiode PD. A photodiode PD is a type of photoelectric device generating charges in proportion to an optical signal incident on each pixel and accumulating the generated charges. According to example embodiments, the photoelectric device may be one of a photodiode (PD), a photocapacitor, a photogate, a pinned photodiode (PPD), a partially pinned photodiode, an organic photodiode (OPD), a quantum dot photodiode (QD-PD), or combinations thereof. In example embodiments, the photoelectric device has been described as being a photodiode PD, but other photoelectric devices described above may be used and example embodiments are not limited to the photodiode PD.

In an example embodiment, each of the plurality of pixel units PU included in the pixel array 110 may support a dual conversion gain mode providing a high conversion gain (HCG) mode and a low conversion gain (LCG) mode. The number of conversion gains provided by the image sensor 100 may be different therefrom.

In an example embodiment, each photodiode may support a dual conversion gain mode. For example, each pixel unit PU may output pixel signals to which a high conversion gain mode and a low conversion gain mode are respectively applied for each photodiode. The image sensor 100 may output an image having a wide dynamic range based on pixel signals to which the high conversion gain mode and the low conversion gain mode are applied, respectively.

The row decoder/driver 120 may select a single row of the pixel array 110 under the control of the timing controller 150. The row decoder/driver 120 may generate a select signal to select one of the plurality of rows. And the row decoder/driver 120 may activate each of the pixel control signal CSn for the pixel units PU corresponding to the selected row in a predetermined order. Then, a reset pixel signal, an image pixel signal, or the like, generated from each of the pixel units PU of the selected row, may be provided to the readout circuit 130.

The readout circuit 130 may include an analog-to-digital converter. The analog-to-digital converter may convert the reset pixel signal and the image pixel signal of the pixel unit PU into a digital signal and output image data. For example, the analog-to-digital converter may sample the reset pixel signal and the image pixel signal using a correlated double sampling method and then convert the sampled signals into digital signals. To this end, the readout circuit 130 may further include a correlated double sampler CDS.

The output buffer 140 may latch the image data in units of columns provided from the readout circuit 130 and output the latched image data. The output buffer 140 may temporarily store the image data output from the readout circuit 130 under the control of the timing controller 150, and then enable the latched image data to be sequentially output by a column decoder.

The timing controller 150 may control the pixel array 110, the row decoder/driver 120, the readout circuit 130, and the output buffer 140. The timing controller 150 may provide control signals such as a clock signal and a timing control signal for the operation of the pixel array 110, the row decoder/driver 120, the readout circuit 130, and the output buffer 140. Although not illustrated, the timing controller 150 may include a logic control circuit, a phase lock loop (PLL) circuit, a timing control circuit, and a communication interface circuit.

In an example embodiment, sub-pixels included in the same pixel unit PU may be separated from each other by a deep trench isolation (DTI) structure. In an example embodiment, at least a portion of boundaries between the sub-pixels included in the same pixel unit PU may be formed with the DTI structure. In an example embodiment, the DTI structure may be formed to have a structure of either front-side deep trench isolation (FDTI) or back-side deep trench isolation (BDTI).

At least one sub-pixel may include a doped region disposed between a photoelectric device and a drain region. The doped region may be doped with an N-type dopant. For example, the doped region may be formed through N-type ion implanting doping. In an example embodiment, the doped region may be doped with an N⁻ doping concentration. In an example embodiment, the doping concentration of the doped region may be lower than a doping concentration of an N-type dopant of the photodiode. The doping concentration of the doped region may be lower than the doping concentration of an N-type dopant of the floating diffusion region.

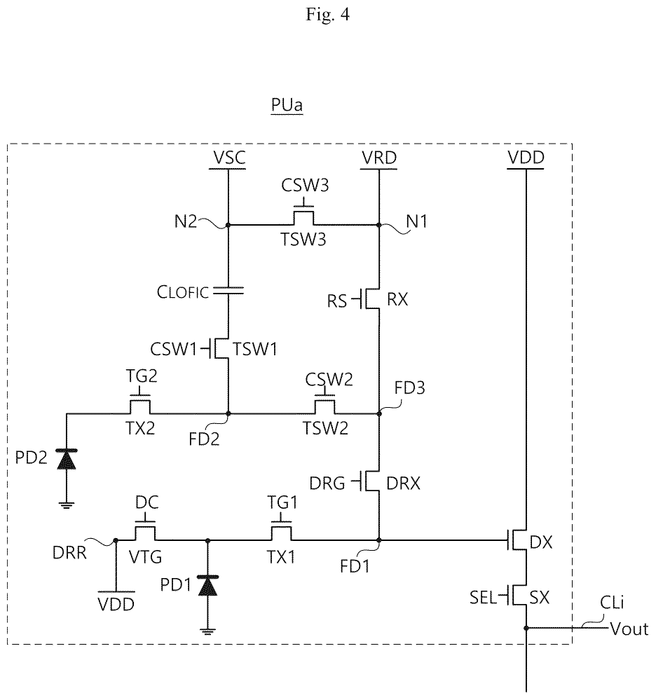

The drain region may be connected to a power supply voltage node. For example, the drain region may be electrically connected to a supply power voltage node VDD of FIG. 4. Alternatively, the drain region may be electrically connected to a reset voltage node VRD or a capacitor voltage node VSC. The drain region may be doped with an N-type dopant. In an example embodiment, the doping concentration of the drain region may be similar to the doping concentration of the floating diffusion region.

A first transistor may be disposed adjacent to the drain region.

In an example embodiment, the first transistor may be configured as a dummy transistor. The first transistor may not perform switching between a turn-on operation and/or a turn-off operation. For example, the first transistor may be maintained in an OFF state. A negative voltage signal having a predetermined magnitude may be continuously supplied to a gate terminal of the first transistor.

In an example embodiment, the doped region may be configured to provide at least a portion of a path through which photocharges overflowed from a photodiode of a single sub-pixel move to a drain region. For example, photocharges overflowed from a photodiode of a single sub-pixel of a pixel unit PU may move through an unintended path. For example, photocharges overflowed from a photodiode may move to an unintended floating diffusion region among a plurality of floating diffusion regions. When the photocharges deviating from the path are recognized as image pixel signals of another sub-pixel, blooming may occur.

The doped region may provide a path through which photocharges overflowed from a photodiode of a single sub-pixel move to the drain region. The overflowed photocharges move to the drain region rather than an unintended floating diffusion region, so that the image sensor 100 may prevent blooming.

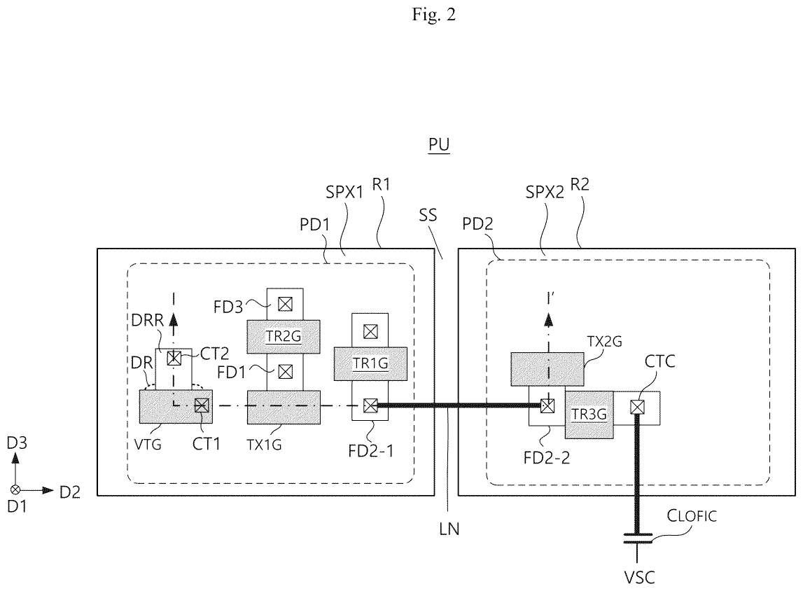

FIG. 2 is a conceptual plan view of a pixel unit according to an example embodiment. The plan view may be a view from a first direction D1, perpendicular to a substrate. FIG. 2 illustrates an example in which a pixel unit PU includes two sub-pixels SPX1 and SPX2. The number of sub-pixels included in the pixel unit according to an example embodiment is not limited to two. The pixel unit PU according to an example embodiment may include more than two sub-pixels.

Referring to FIG. 2, in an example embodiment, a first sub-pixel SPX1 may be disposed in a first region R1 and a second sub-pixel SPX2 may be disposed in a second region R2. The first sub-pixel SPX1 and the second sub-pixel SPX2 may be separated from each other by a separation structure SS. The separation structure SS may be a DTI structure.

The first sub-pixel SPX1 disposed in the first region may include a first photodiode PD1, a gate terminal TX1G of a first transfer transistor, a doped region DR, a drain region DRR, and a gate terminal VTG of a first transistor. The first sub-pixel SPX1 may include a plurality of floating diffusion regions FD1, FD2-1, and FD3.

The second sub-pixel SPX2 disposed in the second region may include a second photodiode PD2, a gate terminal TX2G of a second transfer transistor, and a contact CTC connected to one end of an overflow capacitor CLOFIC. The second sub-pixel SPX2 may include at least one floating diffusion region FD2-2.

The first sub-pixel SPX1 and/or the second sub-pixel SPX2 may include other pixel circuits such as a drive transistor, a select transistor, and a reset transistor. The first sub-pixel SPX1 and/or the second sub-pixel SPX2 may share pixel circuits. FIG. 2 illustrates an example of gate terminals of transistor of the pixel circuits without specifying the gate terminals. For example, gate terminals TR1G, TR2G, and TR3G may each be a gate terminal of any one of a drive transistor, a select transistor, and a reset transistor. The arrangement of the pixel circuits may be different from that of FIG. 2, depending on a layout. For example, the number of active regions formed in each sub-pixel may be different from that of FIG. 2, and the pixel circuits may be disposed to be different from those illustrated in FIG. 2.

A pixel unit PU according to an example embodiment may include a plurality of floating diffusion regions. In an example embodiment, one of the plurality of floating diffusion regions may include partial floating diffusion regions disposed in other regions. For example, referring to FIG. 2, the second floating diffusion region may include partial floating diffusion regions FD2-1 and FD2-2, respectively disposed in the first region R1 and the second region R2. The partial floating diffusion regions FD2-1 and FD2-2 may be electrically connected to each other through an interconnection LN and have the same potential.

FIG. 2 illustrates an example in which a second floating diffusion region, connected to the second photodiode PD2 and the gate terminal TX2G of the second transfer transistor of the second sub-pixel SPX2, is separated. However, other floating diffusion regions may be separated, and the separated partial floating diffusion regions may be disposed in different regions, respectively. The separated partial floating diffusion regions may be electrically connected to each other through an interconnection.

At least a portion of boundaries between different regions may be separated by a separation structure. For example, the first region R1 and the second region R2 may be separated by a separation structure SS. In an example embodiment, the separation structure SS may be a DTI structure and include a conductive layer and a separation insulating layer.

The first sub-pixel SPX1 may include a doped region DR, a drain region DRR, and a gate terminal VTG of a first transistor. When viewed in a first direction D1 perpendicular to a plane of the substrate, at least a portion of the doped region DR may be disposed to overlap the gate terminal VTG of the first transistor. The gate terminal VTG of the first transistor may be a vertical gate. When viewed in the first direction D1, at least a portion of the doped region DR may be disposed to overlap the drain region DRR.

The gate terminal VTG of the first transistor may be electrically connected to a contact CT1. In an example embodiment, the contact CT1 may receive a control signal that always maintains the first transistor in an OFF state. In an example embodiment, the contact CT1 may receive a control signal from a comparator circuit to turn on or off the first transistor.

The drain region DRR may be electrically connected to a contact CT2. The contact CT2 may be electrically connected to a power supply voltage node.

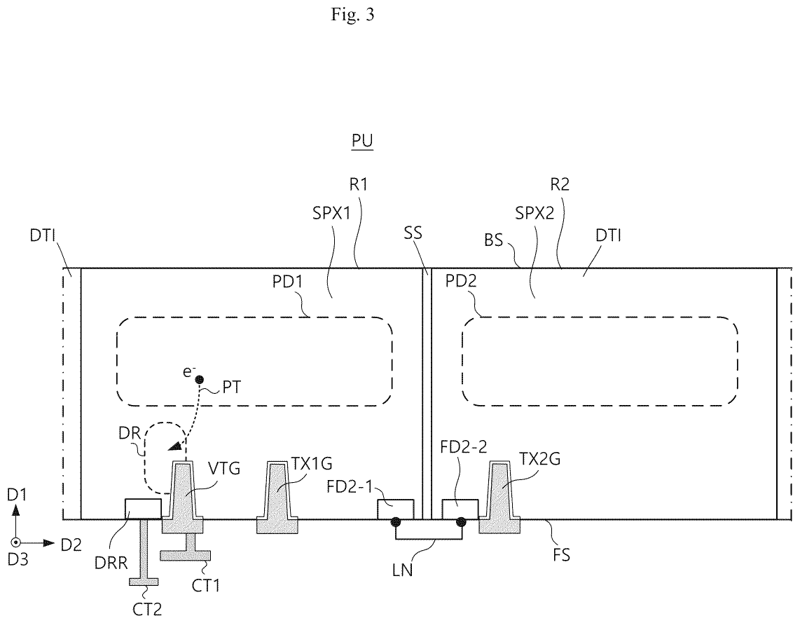

FIG. 3 is a conceptual diagram illustrating an example of a cross-section taken along line I-I′ of the layout of the pixel unit PU of FIG. 2. Descriptions, identical or substantially the same as those provided with reference to FIG. 2, are omitted for brevity.

Referring to FIG. 3, in the pixel unit PU, the first sub-pixel SPX1 may be disposed in the first region R1 and the second sub-pixel SPX2 may be disposed in the second region R2.

In an example embodiment, the first sub-pixel SPX1 and the second sub-pixel SPX2 may include a first photodiode PD1 and a second photodiode PD2 within a substrate having a first surface FS and a second surface BS, respectively. Each of the first photodiode PD1 and the second photodiode PD2 may be disposed within the substrate and may be a region doped with an N-type dopant.

In an example embodiment, each of the first sub-pixel SPX1 and the second sub-pixel SPX2 may include gate terminals TX1G and TX2G of a transfer transistor having at least a portion extending in a first direction D1, an internal direction perpendicular to a plane of the substrate. The gate terminals TX1G and TX2G may be vertical gates.

In an example embodiment, the first sub-pixel SPX1 and the second sub-pixel SPX2 may be separated from each other by a separation structure SS. The separation structure may be a DTI structure.

In the pixel unit PU according to an example embodiment, the second floating diffusion region may be separated and disposed in the first sub-pixel SPX1 and the second sub-pixel SPX2, which are separated by the DTI structure, respectively. For example, the second floating diffusion region may include a first partial floating diffusion region FD2-1 disposed in the first sub-pixel SPX1 and a second partial floating diffusion region FD2-2 disposed in the second sub-pixel SPX2.

In the pixel unit PU according to an example embodiment, the first sub-pixel SPX1 may include a doped region DR doped with an N-type dopant. The doped region DR may be disposed at a predetermined depth from the first surface FS in a first direction D1 perpendicular to the first surface FS. The doped region DR may be disposed between the first photodiode PD1 and the drain region DRR disposed in the first sub-pixel SPX1. For example, the center of the doped region DR may be disposed closer to the first surface FS in the first direction D1 perpendicular to the first surface FS than the center of the first photodiode PD1, and may be disposed farther from the first surface FS in the first direction D1 perpendicular to the first surface FS than the center of the drain region DRR.

In an example embodiment, the doped region DR may be disposed to be spaced apart from the first photodiode PD1 in the first direction D1.

In an example embodiment, at least a portion of the doped region DR may overlap the gate terminal VTG of the first transistor. For example, referring to FIG. 3, when viewed in the first direction D1 perpendicular to the first surface FS, at least a portion of the doped region DR may overlap the gate terminal VTG of the first transistor.

In an example embodiment, when viewed in the first direction D1, a portion of the doped region DR may overlap the gate terminal VTG of the first transistor, and another portion may overlap the drain region DRR.

In an example embodiment, unlike that illustrated in FIG. 3, when viewed in the first direction D1, a portion of the doped region DR may overlap the gate terminal VTG of the first transistor and may not overlap the drain region DRR.

Referring to FIG. 3, the doped region DR may be disposed between the drain region DRR and the first photodiode PD1. In an example embodiment, the doped region DR may be doped with an N-type dopant at a lower concentration than that of the first photodiode PD1. Also, the doped region DR may be doped with an N-type dopant at a lower concentration than that of the floating diffusion regions. A potential difference may occur between the doped region DR and the first photodiode PD1 due to a difference in the concentration of N-type dopants. Therefore, charges e⁻ overflowed from the first photodiode PD1 may move to the drain region DRR due to the potential difference occurring along a path PT. For example, the charges overflowed from the first photodiode PD1 may not move to the first partial floating diffusion region FD2-1 of the second floating diffusion region. As a result, a blooming issue, in which the charges overflowed from the first photodiode PD1 are read as image pixel signals of the second photodiode PD2, may be prevented.

FIG. 4 is a circuit diagram illustrating a pixel unit of an image sensor according to an example embodiment. A pixel unit PUa of FIG. 4 may correspond to the pixel unit PU of FIG. 1.

The pixel unit PUa according to an example embodiment may include at least two sub-pixels. Each of the sub-pixels may include an individual photodiode. For example, the pixel unit PUa may include two sub-pixels, with one sub-pixel including a first photodiode PD1 and the other sub-pixel including a second photodiode PD2. In an example embodiment, the first photodiode PD1 may be a large photodiode LPD having a relatively large light-receiving area, and the second photodiode PD2 may be a small photodiode SPD having a relatively small light-receiving area. A circuit of the pixel unit PUa according to an example embodiment will be described in detail with reference to FIG. 4.

Referring to FIG. 4, the pixel unit PUa may include a plurality of photodiodes PD1 and PD2, a plurality of transistors TX1, TX2, RX, DRX, DX, SX, TSW1, TSW2, and TSW3, an overflow capacitor CLOFIC, a first transistor VTG, and a drain region DRR.

The transfer transistors TX1 and TX2 connected to each of the plurality of photodiodes PD1 and PD2 may be turned on or off individually in response to transfer control signals TG1 and TG2 provided from the row decoder/driver 120 of FIG. 1. The transfer transistors TX1 and TX2 may transfer charges, accumulated in the connected photodiodes PD1 and PD2, to floating diffusion regions FD1 and FD2, respectively. For example, the photocharges generated in the first photodiode PD1 may be moved to the first floating diffusion region FD1 by the turned-on first transfer transistor TX1. The photocharges generated in the second photodiode PD2 may be moved to the second floating diffusion region FD2 by the turned-on second transfer transistor TX2.

The plurality of floating diffusion regions FD1, FD2, and FD3 may be connected to each other through at least one transistor. Referring to FIG. 4, in an example embodiment, the second floating diffusion region FD2 and the third floating diffusion region FD3 may be connected by a second switch transistor TSW2. The first floating diffusion region FD1 and the third floating diffusion region FD3 may be connected by a gain control transistor DRX. At least a portion of the floating diffusion regions FD1, FD2, and FD3 may be electrically coupled to or isolated from each other during a readout operation.

In an example embodiment, the overflow capacitor CLOFIC may be a lateral overflow integration capacitor LOFIC. In an example embodiment, one end of the overflow capacitor CLOFIC may be connected to the second floating diffusion region FD2 through the first switch transistor TSW1. Alternatively, in an example embodiment, one end of the overflow capacitor CLOFIC may be directly connected to the second floating diffusion region FD2. The other end of the overflow capacitor CLOFIC may be connected to a voltage node VSC. The charges overflowed from the second photodiode PD2 may be accumulated in the overflow capacitor CLOFIC via the second floating diffusion region FD2.

The overflow capacitor CLOFIC may be connected to the second floating diffusion region FD2 through the first switch transistor TSW1. The first switch transistor SW1 may be turned on or off in response to a first control signal CSW1 provided from the row decoder/driver 120 of FIG. 1 during the readout operation of the second photodiode PD2. For example, the first switch transistor TSW1 may be turned on in a low conversion gain (LCG) mode of the second photodiode PD2 to electrically couple the capacitance of the overflow capacitor CLOFIC to the first floating diffusion region FD1 together with the second floating diffusion region FD2 and the third floating diffusion region FD3.

The first floating diffusion region FD1 may be connected to the third floating diffusion region FD3 through the gain control transistor DRX. The gain control transistor DRX may be turned on or off in response to a gain control signal DRG provided from the row decoder/driver 120 of FIG. 1. For example, the gain control transistor DRX may be turned on in a low conversion gain (LCG) mode of the first photodiode PD1 to electrically couple the capacitance of the third floating diffusion region FD3 to the first floating diffusion region FD1. The gain control transistor DRX may be turned off in a high conversion gain (HCG) mode of the first photodiode PD1 to electrically isolate the third floating diffusion region FD3 from the first floating diffusion region FD1.

The first floating diffusion region FD1 may be connected to a gate of a drive transistor DX operating as a source follower amplifier.

One end of the drive transistor DX may be connected to a power supply voltage node VDD, and the other end may be connected to a select transistor SX. The gate of the drive transistor DX may be connected to the first floating diffusion region FD1 and may provide the role of a source follower amplifier. For example, the drive transistor DX may convert a potential of the first floating diffusion region FD1 into a voltage. The drive transistor DX may output a pixel signal Vout to a column line CLi via the select transistor SX. Alternatively, the drive transistor DX may output a pixel signal Vout to the column line CLi, and the pixel signal Vout converts the potential of the first floating diffusion region FD1, to which the second floating diffusion region FD2 and/or the third floating diffusion region FD3 is electrically coupled, into a voltage.

The select transistor SX may be turned on in response to the selection of the pixel unit PUa. The select transistor SX may be turned on by a select signal SEL. In an example embodiment, the select signal SEL may be provided for each row. When the select transistor SX is turned on, a voltage amplified through the drive transistor DX may be transmitted to a drain of the select transistor SX. The select transistor SX may output the received voltage to the column line CLi.

In an example embodiment, one end of the reset transistor RX may be connected to the third floating diffusion region FD3, and the other end may be connected to the reset voltage node VRD through a first node N1. One end of the overflow capacitor CLOFIC may be connected to a capacitor voltage node VSC through a second node N2. In an example embodiment, the magnitude of the voltage provided through the reset voltage node VRD may be the same as or different from the magnitude of the voltage provided through the capacitor voltage node VSC. In addition, at least one of the magnitude of the voltage provided through the reset voltage node VRD and the magnitude of the voltage provided through the capacitor voltage node VSC may be the same as or different from the magnitude of the voltage provided from the power supply voltage node VDD.

The first node N1 and the second node N2 may be connected to each other through a third switch transistor TSW3. The third switch transistor TSW3 may be turned on during an operation of reading a reset signal in a low conversion gain (LCG) mode of the second photodiode PD2.

The reset transistor RX may reset at least one of the first, second, and third floating diffusion regions FD1, FD2, and FD3 in response to a reset control signal RS. For example, the source of the reset transistor RX may be connected to the third floating diffusion region FD3, as illustrated in FIG. 2. When a reset control signal RS is activated while a gain control signal DRG activated, a gain control transistor DRX may be turned on and a reset voltage may be provided from the first node N1 to the first floating diffusion region FD1. In addition, when the reset control signal RS and a second control signal CSW2 are activated, the reset voltage may be provided from the first node N1 to the second and third floating diffusion regions FD2 and FD3. During a readout operation, the gain control transistor DRX and the second switch transistor TSW2 may be simultaneously turned on, only one of the transistors DRX and TSW2 may be turned on, or the transistors DRX and TSW2 may be simultaneously turned off.

According to an example embodiment, the sub-pixels of the pixel unit PUa may be separated by a DTI structure. Regions separated by the DTI structure in the pixel unit PUa may include a first region and a second region. One of the sub-pixels may be disposed in the first region, and another sub-pixel may be disposed in the second region. The first region and the second region may be separated from each other by the DTI structure.

In an example embodiment, the second floating diffusion region FD2 may include a first partial floating diffusion region and a second partial floating diffusion region with a DTI structure interposed therebetween. For example, the first partial floating diffusion region may be disposed in the first region, and the second partial floating diffusion region may be disposed in the second region. The first partial floating diffusion region and the second partial floating diffusion region may be electrically connected to each other and have the same potential.

In an example embodiment, the third floating diffusion region FD3 may include a (3-1)-th partial floating diffusion region and a (3-2)-th partial floating diffusion region with a DTI structure interposed therebetween. For example, the (3-1)-th partial floating diffusion region may be disposed in the first region, and the (3-2)-th partial floating diffusion region may be disposed in the second region. The (3-1)-th partial floating diffusion region and the (3-2)-th partial floating diffusion region may be electrically connected to each other and have the same potential.

The pixel unit PUa may include at least one doped region. For example, the doped region may be disposed between the first photodiode PD1 and the drain region DRR within the substrate.

The drain region DRR may be connected to the first photodiode PD1 with the first transistor VTG interposed therebetween. The drain region DRR may be electrically connected to a power supply voltage node VDD. Unlike that illustrated in FIG. 4, the drain region DRR may be connected to a reset voltage node VRD or a capacitor voltage node VSC.

In an example embodiment, the first transistor VTG may receive a control signal DC. For example, the control signal DC may continuously maintain the first transistor VTG in an OFF state. Alternatively, for example, the control signal DC may switch the first transistor VTG between an ON state and an OFF state.

In an example embodiment, when the doped region is disposed between the first photodiode PD1 and the drain region DRR, photocharges overflowed from the first photodiode PD1 may move to the drain region DRR via the doped region. Accordingly, when the second floating diffusion region FD2 includes a first partial floating diffusion region disposed in the first region and a second partial floating diffusion region disposed in the second region, the photocharges overflowed from the first photodiode PD1 may not move to the first partial floating diffusion region but may move to the drain region DRR via the doped region. Charges, moved to the drain region DRR, may move to the power supply voltage node VDD. As a result, blooming may be prevented.

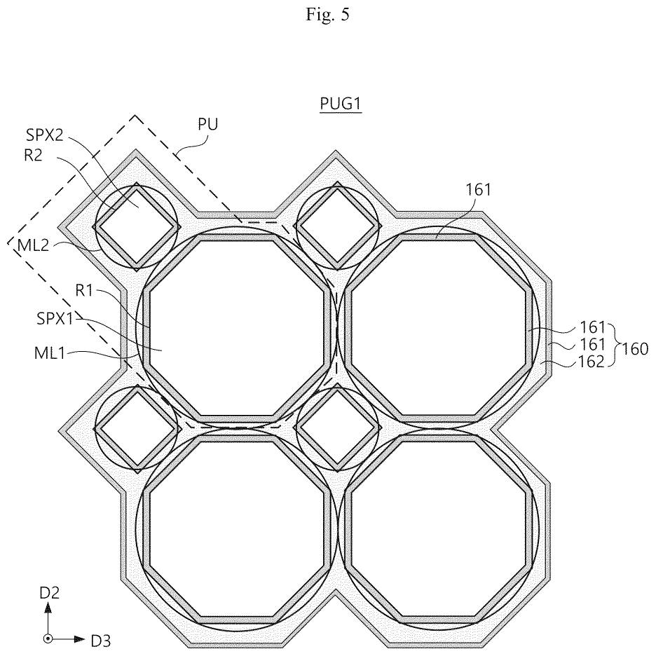

FIGS. 5 to 7 are conceptual plan views of pixel units of an image sensor according to example embodiments. For example, FIGS. 5 to 7 may be plan views viewed from a first direction D1 perpendicular to a plane of a substrate.

A pixel units, included in pixel unit groups PUG1, PUG2, and PUG3 of FIGS. 5 to 7 may correspond to the pixel unit PU of FIG. 1. The pixel unit groups PUG1, PUG2, and PUG3 of FIGS. 5 to 7 may correspond to a portion of a pixel array 110 of an image sensor 100. For example, FIGS. 5 to 7 illustrate examples of a pixel unit group including four pixel units.

Pixel units according to an example embodiment may constitute a pixel unit group PUG for every predetermined number of pixel units. FIGS. 5 to 7 respectively illustrate exemplary pixel unit groups PUG1, PUG2, and PUG3, each including four pixel units. Unlike the example embodiments of FIGS. 5 to 7, a pixel unit group may include a smaller or larger number of pixel units than four.

In an example embodiment, each pixel unit of each of the pixel unit group PUG1, PUG2, and PUG3 may include a plurality of sub-pixels. For example, each pixel unit of each of the pixel unit groups PUG1, PUG2, and PUG3 of FIGS. 5 to 7 may include two sub-pixels SPX1 and SPX2. In an example embodiment, the first sub-pixel SPX1 may include a large photodiode LPD, and the second sub-pixel SPX2 may include a small photodiode SPD.

In FIGS. 5 to 7, an example is provided in which each of the pixel unit groups PUG1, PUG2, and PUG3 includes four pixel units and the pixel unit PU includes two sub-pixels SPX1 and SPX2.

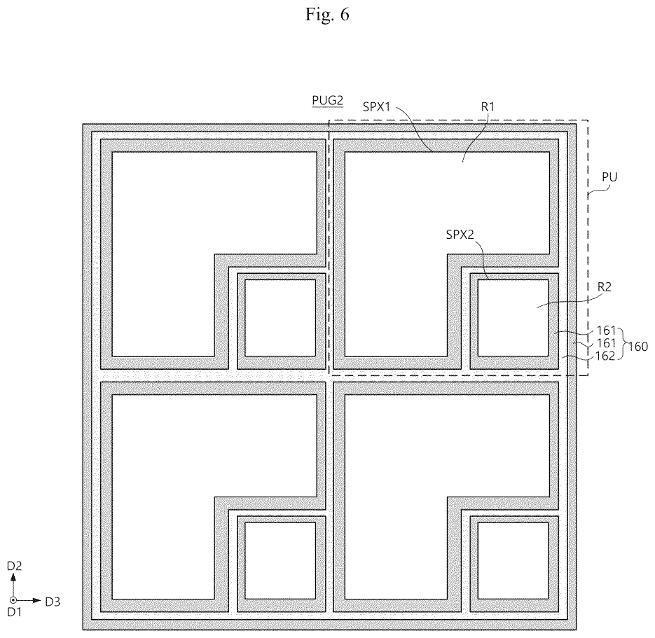

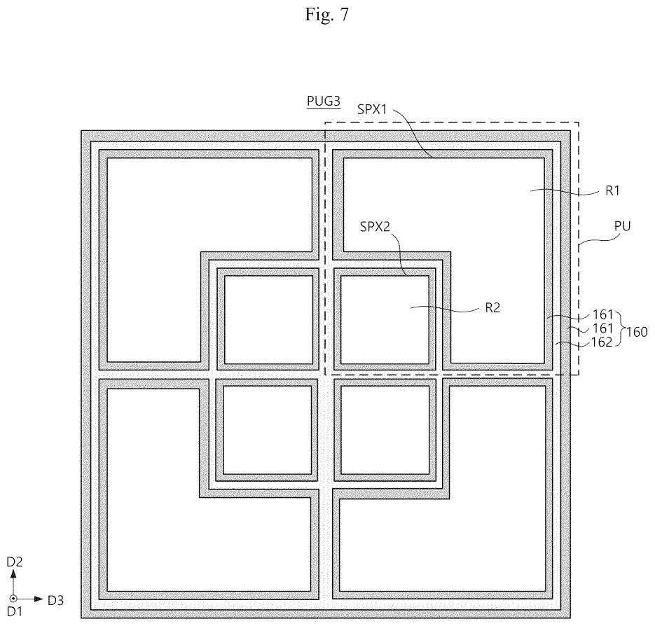

Referring to FIGS. 5 to 7, the first sub-pixel SPX1 may be disposed in a first region R1, and the second sub-pixel SPX2 may be disposed in a second region R2. Referring to FIG. 5, the first sub-pixel SPX1 may include a first microlens ML1, and the second sub-pixel SPX2 may include a second microlens ML2. Although not illustrated in FIGS. 6 and 7, similarly, each pixel unit PU of each of the pixel unit groups PUG2 and PUG3 may include an individual microlens. Alternatively, the sub-pixels SPX1 and SPX2 included in the pixel unit PU of each of the pixel unit groups PUG2 and PUG3 may include individual microlenses.

Referring to FIGS. 5 to 7, the sub-pixels SPX1 and SPX2 of the pixel unit PU may be separated from each other by a separation structure. In an example embodiment, the first region R1 and the second region R2 may be separated from each other by a DTI structure. In an example embodiment, the first region R1 and the second region R2 may include at least a portion of a separation structure separating the sub-pixels SPX1 and SPX2. In an example embodiment, the separation structure may include a DTI structure.

Referring to FIGS. 5 to 7, the pixel unit PU may include a separation structure 160 disposed between the sub-pixels SPX1 and SPX2.

Referring to FIGS. 5 to 7, in an example embodiment, the separation structure 160 may include a conductive layer 161 and a separation insulating layer 162. The conductive layer 161 may include a conductive material such as polysilicon or metal. The separation insulating layer 162 may include a silicon oxide, a silicon nitride, a metal oxide, or combinations thereof.

Referring to FIGS. 5 to 7, in an example embodiment, at least a portion of the separation structure of one pixel unit PU may be connected to at least a portion of the separation structure of another pixel unit PU. For example, the conductive layer of the separation structure of one pixel unit PU may extend, and the extending conductive layer may form a conductive layer of the separation structure of another pixel unit PU.

Referring to FIGS. 5 to 7, in an example embodiment, each of the pixel unit groups PUG1, PUG2, and PUG3 may include a separation structure separating one pixel unit from another pixel unit.

In an example embodiment, the separation structure may be formed to separate one sub-pixel from another sub-pixel within the pixel unit PU.

Referring to FIGS. 5 to 7, in an example embodiment, some of components of the pixel unit PU may be separated and disposed in the sub-pixels SPX1 and SPX2. For example, some of the components of the pixel unit PU described with reference to FIG. 4 may be disposed in the first sub-pixel SPX1, and other components may be disposed in the second sub-pixel SPX2.

In an example embodiment, at least one component may be separated and disposed in both sub-pixels SPX1 and SPX2. For example, at least one of the plurality of floating diffusion regions may be separated and disposed in both sub-pixels SPX1 and SPX2.

In an example embodiment, the second floating diffusion region FD2 of FIG. 4 may be separated into a first partial floating diffusion region (e.g., first partial floating diffusion region FD2-1 of FIG. 2), disposed in the first region, and a second partial floating diffusion region (e.g., FD2-2 second partial floating diffusion region of FIG. 2) disposed in the second region. The first partial floating diffusion region (e.g., first partial floating diffusion region FD2-1 of FIG. 2) and the second partial floating diffusion region FD2-2 may be electrically connected to each other and have the same potential.

In an example embodiment, the third floating diffusion region FD3 may be separated into a (3-1)-th partial floating diffusion region, disposed in the first region, and a (3-2)-th partial floating diffusion region disposed in the second region. The (3-1)-th floating diffusion region and the (3-2)-th floating diffusion region may be electrically connected to each other and have the same potential.

Referring to FIG. 5, in an example embodiment, when viewed in the first direction D1, the first sub-pixel SPX1 may be disposed in an octagonal first region R1 and the second sub-pixel SPX2 may be disposed in a rectangular second region R2.

Referring to FIG. 6, in an example embodiment, when viewed in the first direction D1, the first sub-pixel SPX1 may be disposed in a rotated L-shaped first region R1, and the second sub-pixel SPX2 may be disposed in a rectangular second region R2. The second sub-pixel SPX2 may be disposed adjacent to a concave shape of the first sub-pixel SPX1. A concave shape of each of the plurality of first sub-pixels SPX1s of the pixel unit group PUG2 may face the same direction.

Referring to FIG. 7, in an example embodiment, when viewed in the first direction D1, the first sub-pixel SPX1 may be disposed in a rotated L-shaped first region R1 and the second sub-pixel SPX2 may be disposed in a rectangular second region R2. The second sub-pixel SPX2 may be disposed adjacent to a concave shape of the first sub-pixel SPX1. Concave shapes of the plurality of first sub-pixels SPX1s of the pixel unit group PXG3 may be disposed adjacent to each other.

The shapes of the first region R1 and the second region R2 are not limited to the shapes illustrated in FIGS. 5 to 7. For example, each of the first region R1 and the second region R2 may have a circular or rectangular shape.

Referring to FIGS. 5 to 7, each of the pixel units PUs of the pixel unit groups PUG1, PUG2, and PUG3 may include a Bayer pattern color filter. For example, pixel units that follow a single diagonal in each of the pixel unit groups PUG1, PUG2, and PUG3 may include a green color filter, while the remaining two pixel units may include a red color filter and a blue color filter, respectively.

Referring to FIGS. 5 to 7, pixel units PUs of each of the pixel unit groups PUG1, PUG2, and PUG3 may include the same color filter. For example, each of the pixel unit groups PUG1, PUG2, and PUG3 of FIGS. 5 to 7 may include the same color filter. A different pixel unit group adjacent to each of the pixel unit groups PUG1, PUG2, and PUG3 may include a color filter corresponding to a different color. For example, the pixel unit groups may be disposed in a Bayer pattern.

Unlike that described above, each pixel unit group may include a color filter corresponding to a color pattern other than the Bayer pattern, and the color pattern of each pixel unit group is not limited to the Bayer pattern.

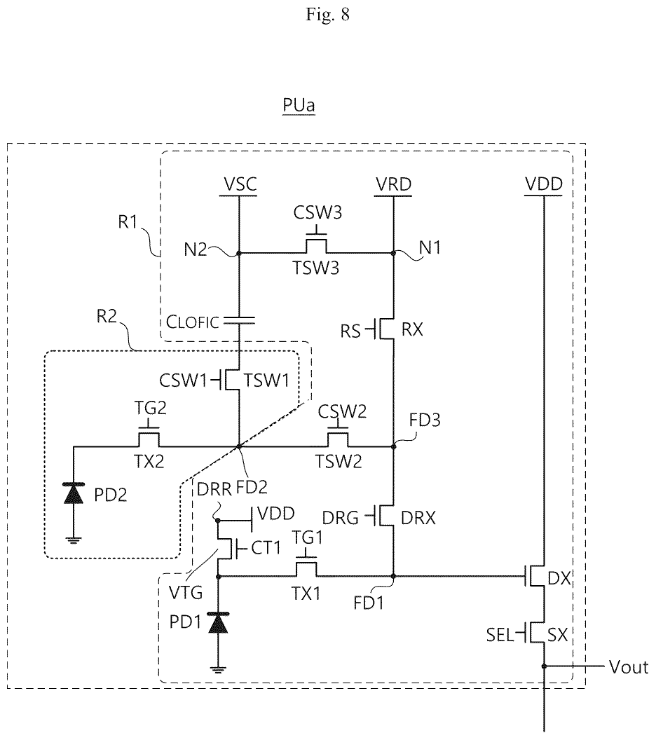

FIG. 8 is a diagram illustrating an example of a pixel unit layout based on a circuit diagram of the pixel unit of FIG. 4. A circuit diagram of a pixel unit PUa of FIG. 8 is the same as the circuit diagram of the pixel unit PUa of FIG. 4.

Referring to FIG. 8, the pixel unit PUa according to an example embodiment may include a second photodiode PD2, a second transfer transistor TX2, a first switch transistor TSW1, and a second floating diffusion region FD2 disposed in a second region R2. Other components of the pixel unit PUa and the second floating diffusion region FD2 may be disposed in the first region R1. For example, among components of the pixel unit PUa, a first photodiode PD1 and a first transfer transistor TX1 may be disposed in the first region R1, and the second photodiode PD2 and the second transfer transistor TX2 may be disposed in the second region R2. Also, the second floating diffusion region FD2 may be separated and disposed in each of the first region R1 and the second region R2. Components other than the first photodiode PD1, the first transfer transistor TX1, the second photodiode PD2, the second transfer transistor TX2, and the second floating diffusion region FD2 may each be disposed in either the first region R1 or the second region R2. The first region R1 and the second region R2 may be regions disposed at different locations when viewed in a direction perpendicular to a plane of a substrate.

In an example embodiment, an overflow capacitor CLOFIC may be disposed in either the first region R1 or the second region R2, or outside the region. In an example embodiment, the overflow capacitor CLOFIC may be configured as an in-pixel capacitor or as a capacitor outside a pixel.

The pixel unit PUa according to an example embodiment may include a drain region DRR, a first transistor VTG, and a doped region disposed in the first region R1. The drain region DRR may be connected to the first photodiode PD1 with the first transistor VTG interposed therebetween. The doped region may be disposed between the first photodiode PD1 and the drain region DRR within a substrate. The drain region DRR may be connected to a power supply voltage node VDD. The first transistor VTG may receive a control signal DC. In an example embodiment, the control signal DC may continuously maintain the first transistor VTG in an OFF state. In an example embodiment, the control signal DC may switch the first transistor VTG between an OFF state and an ON state.

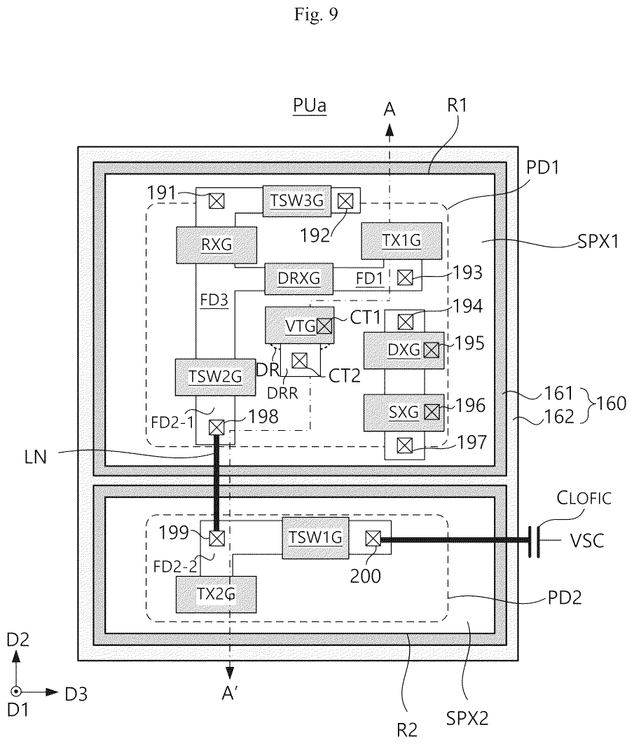

FIG. 9 is a simplified plan view illustrating an example of the layout of the pixel unit of FIG. 8. The plan view may be a view from a first direction D1, perpendicular to a substrate. Descriptions, identical or substantially the same as those provided with reference to FIG. 2, are omitted for brevity.

Referring to FIG. 9, in an example embodiment, the first sub-pixel SPX1 may be disposed in a first region R1 and the second sub-pixel SPX2 may be disposed in a second region R2. The first sub-pixel SPX1 disposed in the first region R1 may include a first photodiode PD1, a gate terminal of a first transfer transistor TX1G, a gate terminal of a drive transistor DXG, a gate terminal of a select transistor SXG, a gate terminal of a reset transistor RXG, a gate terminal of a second switch transistor TSW2G, a gate terminal of a third switch transistor TSW3G, a first floating diffusion region FD1, and a third floating diffusion region FD3.

According to an example embodiment, the first sub-pixel SPX1 of the pixel unit PUa may include a doped region DR, a gate terminal of a first transistor VTG, and a drain region DRR.

The second sub-pixel SPX2 disposed in the second region R2 may include a second photodiode PD2, a gate terminal of a second transfer transistor TX2G, and a gate terminal of a first switch transistor TSW1G.

The number and shape of active regions illustrated in FIG. 9 are merely exemplary, and a pixel unit PUa may be formed from active regions of different numbers and shapes.

In an example embodiment, a contact 191 may be connected to the reset voltage node VRD of FIG. 6, and a contact 192 may be connected to a capacitor voltage node VSC and one end of an overflow capacitor CLOFIC. A contact 193 may be connected to a contact 195. A contact 194 may be connected to the power supply voltage node VDD, a contact 196 may receive a select signal SEL, and a contact 197 may be connected to a column line. A contact 198 may be connected to a contact 199, and a contact 200 may be connected to the other end of the overflow capacitor CLOFIC.

The first region R1 and the second region R2 may be separated by a separation structure 160. In an example embodiment, the separation structure 160 may be a DTI structure and include a conductive layer 161 and a separation insulating layer 162.

The layout described in FIG. 9 is merely exemplary, and some components may be disposed in a different sub-pixel, unlike that illustrated in FIG. 9. For example, a gate terminal TSW3G of a third switch transistor may be disposed in the second sub-pixel SPX2.

In an example embodiment, in the pixel unit PUa, one of the plurality of floating diffusion regions may include partial floating diffusion regions separated and disposed in different regions. For example, referring to FIG. 2, the second floating diffusion region may include partial floating diffusion regions FD2-1 and FD2-2, which are separated and disposed in the first region R1 and the second region, respectively. The partial floating diffusion regions FD2-1 and FD2-2 may be electrically connected to each other through an interconnection LN and have the same potential.

FIG. 9 illustrates an example in which the second floating diffusion region FD2 connected to the second photodiode PD2 and the gate terminal TX2G of the second transfer transistor of the second sub-pixel SPX2 is separated, but other floating diffusion regions may be separated and disposed in different regions.

At least a portion of the doped region DR of the pixel unit PUa according to an example embodiment may overlap the gate terminal VTG of the first transistor. The gate terminal VTG of the first transistor may be electrically connected to a contact CT1. In an example embodiment, the contact CT1 may receive a control signal that always maintains the first transistor in an OFF state. In an example embodiment, the contact CT1 may receive a control signal from a comparator circuit that turns on or off the first transistor.

The drain region DRR may be electrically connected to a contact CT2. The contact CT2 may be electrically connected to a power supply voltage node.

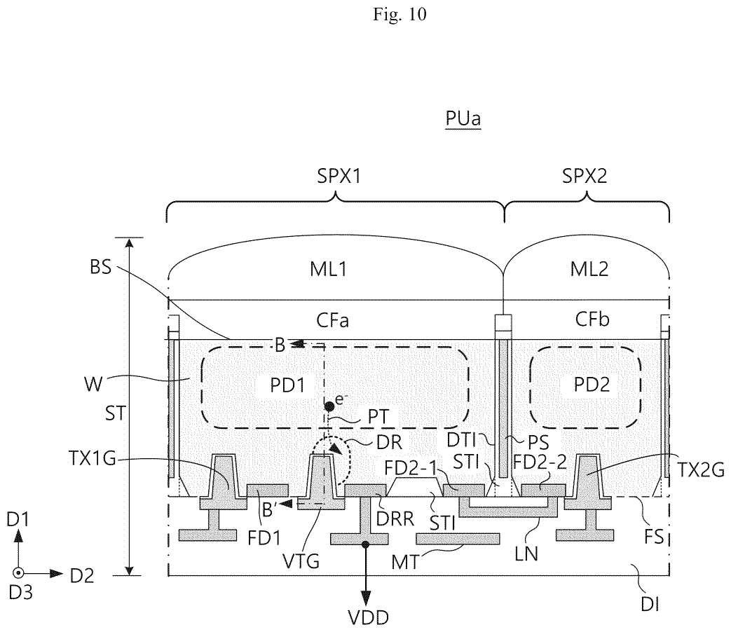

FIG. 10 is a diagram illustrating a conceptual example of a cross-section taken along A-A′ in the layout of the pixel of FIG. 9. Descriptions, identical or substantially the same as those provided with reference to FIGS. 3 and 9, are omitted for brevity. A pixel unit PUa of FIG. 10 may correspond to the pixel unit PU of FIG. 1.

Referring to FIG. 10, the pixel unit PUa may include a structure ST and an insulating layer DI. The structure ST may include a substrate W having a first surface FS and a second surface BS. The insulating layer DI may include an interconnection layer MT for transmitting electrical signals.

The pixel unit PUa may include a first sub-pixel SPX1 and a second sub-pixel SPX2.

Each of the first sub-pixel SPX1 and the second sub-pixel SPX2 may include microlenses ML1 and ML2 and color filters CFa and CFb. The color filters CFa and CFb may be color filters of the same color or different colors.

In an example embodiment, unlike that illustrated in FIG. 10, the first sub-pixel SPX1 and the second sub-pixel SPX2 may share a single microlens or include color filters corresponding to the same color.

The first sub-pixel SPX1 and the second sub-pixel SPX2 may be separated by a separation structure. In an example embodiment, the separation structure may include a DTI structure and a shallow trench isolation structure STI. For example, the DTI structure may include an FDTI structure. The DTI structure may include a conductive layer PS therein. The conductive layer PS may include a conductive material such as polysilicon or metal. A space between an internal surface of the DTI structure and a conductive layer PS may include a separation insulating layer filled with a silicon oxide, a silicon nitride, a metal oxide, or combinations thereof. One end of the DTI structure may be connected to a shallow trench isolation structure STI. In an example embodiment, the shallow trench isolation structure STI may include a shallow trench isolation.

The shallow trench isolation STI may be formed in the substrate W to define an active region. The shallow trench isolation STI may fill a shallow trench recessed into the substrate W from a first surface FS of a substrate W. Accordingly, the shallow trench isolation STI may be disposed adjacent to the first surface FS of the substrate W. The shallow trench isolation STI may be exposed by the first surface FS. A portion of the shallow trench isolation STI may vertically overlap a portion of the DTI structure DTI. The shallow trench isolation STI may be connected to the DTI structure DTI.

The shallow trench isolation STI may include at least one insulating material among a variety of insulating materials. For example, the shallow trench isolation STI may include at least one of a silicon oxide, a silicon nitride, or a silicon oxynitride.

In an example embodiment, the first sub-pixel SPX1 of the pixel unit PUa may include a doped region DR doped with an N-type dopant. The doped region DR may extend further from the first surface FS than the drain region DRR. The doped region DR may be disposed closer to the first surface FS than the first photodiode PD1.

In an example embodiment, the doped region DR may be disposed at a predetermined distance from the first photodiode PD1. A doped region doped with a P-type dopant may be present between the doped region DR and the first photodiode PD1.

In an example embodiment, the doped region DR may be disposed at a predetermined distance from the drain region DRR. The distance between the doped region DR and the drain region DRR may be smaller than a distance between the doped region DR and the first photodiode PD1.

The doped region DR may be disposed between the first photodiode PD1 and the drain region DRR. Photocharge e⁻ overflowed from the first photodiode PD1 may move to the drain region DRR through the doped region DR along a virtual path PT. The doped region DR may be doped with an N-type dopant having a lower concentration than that of the first photodiode. Therefore, the photocharges e⁻ overflowed from the first photodiode PD1 may move to the drain region DRR through the doped region DR and may not exit to the first partial floating diffusion region FD2-1. The drain region DRR may be connected to a power supply voltage node VDD. As a result, blooming may be prevented.

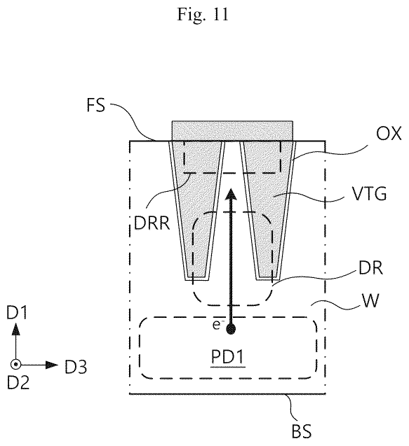

FIG. 11 is a diagram illustrating an example of a cross-section taken along B-B′ in a cross-sectional view of the pixel in FIG. 10. A drain region DRR does not overlap an imaginary cut line B-B′ of FIG. 10. In addition, when viewed in a second direction D2, the drain region DRR is disposed behind a gate terminal TX1G of a first transfer transistor but is illustrated for reference in FIG. 11. Descriptions, identical or substantially the same as those provided with reference to FIGS. 3 and 10, are omitted for brevity.

In an example embodiment, the gate terminal TX1G of the first transfer transistor may be a dual gate terminal. When viewed in the second direction D2, a portion of the doped region DR may be disposed between a plurality of protrusions extending in a first direction D1 of the dual gate terminal. A portion of the doped region DR may be disposed closer to a second surface BS of a substrate W than the plurality of protrusions. For example, the doped region DR may extend deeper into the substrate W than the gate terminal TX1G of the first transfer transistor. The drain region DRR may be disposed closer to the first surface FS of the substrate W than the doped region DR.

In an example embodiment, when viewed in the second direction D2, the doped region DR may not overlap the drain region DRR.

Photocharges e− overflowed from the first photodiode PD1 may move in a direction of the first surface FS and move to the drain region DRR through the doped region DR.

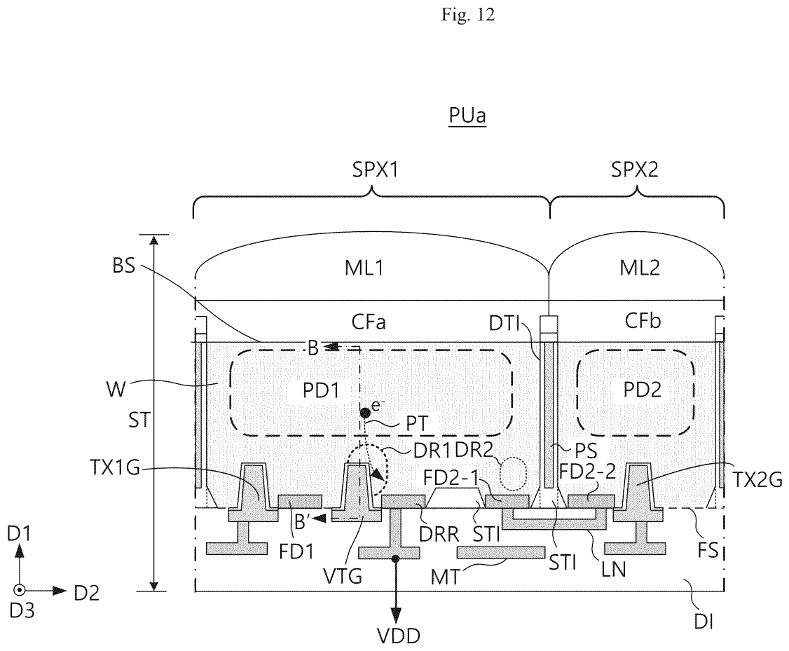

FIG. 12 is a diagram illustrating an example of a cross-section taken along A-A′ in the layout of the pixel of FIG. 9. Descriptions, identical or substantially the same as those provided with reference to FIG. 9, are omitted for brevity. A pixel unit PUa of FIG. 12 may correspond to the pixel unit PU of FIG. 1.

According to an example embodiment, unlike the pixel unit PU described with reference to FIG. 10, the pixel unit PUa may include a first doped region DR1 doped with an N-type dopant and a second doped region DR2 doped with a P-type dopant. The first doped region DR1 may be substantially the same as the doped region DR described with reference to FIG. 10.

The second doped region DR2 may be disposed between the first photodiode PD1 and the first partial floating diffusion region FD2-1.

In an example embodiment, the second doped region DR2 may extend closer to the first surface FS than the first doped region DR1 with respect to the first surface FS. For example, a distance between the second doped region DR2 and the first photodiode PD1 may be larger than a distance between the first doped region DR1 and the first photodiode PD1. Accordingly, a decrease in full-well capacity FWC of the first photodiode PD1, caused by the second doped region DR2, may be prevented.

The second doped region DR2 may prevent charges, overflowed from the first photodiode PD1, from exiting to the first partial floating diffusion region FD2-1. As a result, blooming may be prevented.

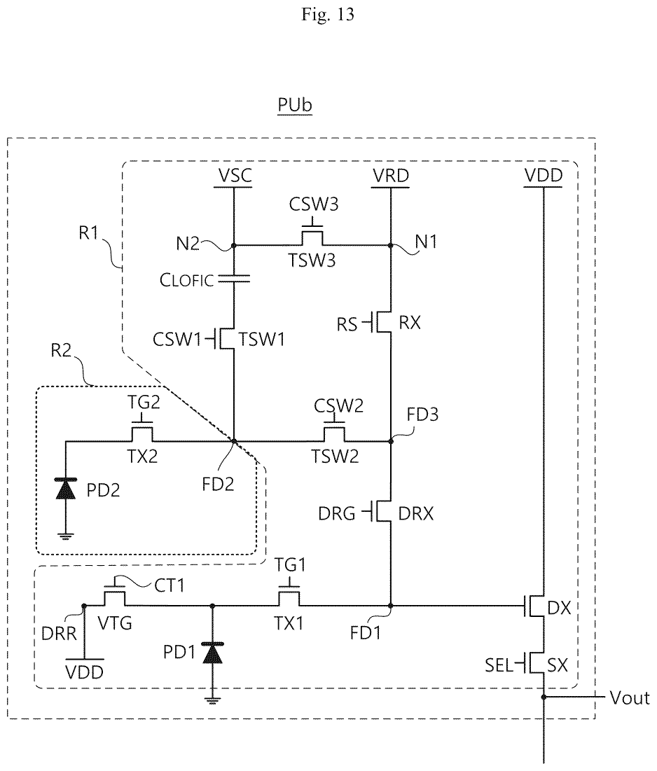

FIG. 13 is a diagram illustrating an example of a pixel unit layout based on the circuit diagram of the pixel unit of FIG. 4. A circuit diagram of a pixel unit PUb of FIG. 13 is the same as the circuit diagram of the pixel unit PUa of FIG. 4. Descriptions, identical or substantially the same as those provided with reference to FIG. 8, are omitted for brevity.

Referring to FIG. 13, unlike the pixel unit PUa described with reference to FIG. 8, a first switch transistor TSW1 of the pixel unit PUb according to an example embodiment may be disposed in a first region R1. A second floating diffusion region FD2 of the pixel unit PUb may be separated and disposed in both the first region R1 and the second region R2, similarly to the pixel unit PUa described with reference to FIG. 8. For example, the second floating diffusion region FD2 may be separated into a first partial floating diffusion region and a second partial floating diffusion region, which are electrically connected to each other. The first partial floating diffusion region may be disposed in the first region R1, and the second partial floating diffusion region may be disposed in the second region R2.

The pixel unit PUb according to an example embodiment may include a drain region DRR, a first transistor VTG, and a doped region disposed in the first region R1, similarly to the pixel unit PUa described with reference to FIG. 8.

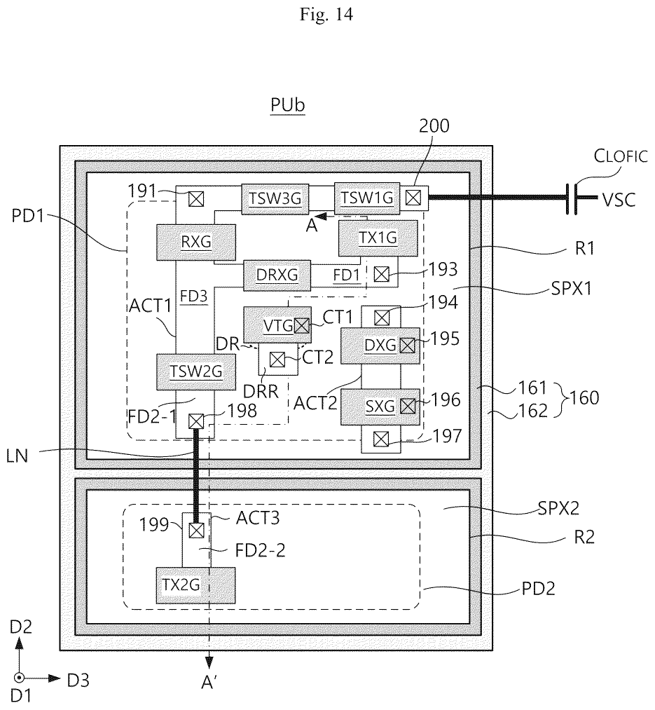

FIG. 14 is a simplified plan view illustrating an example of the layout of the pixel unit of FIG. 13. The plan view may be a view from a first direction D1, perpendicular to a substrate. Descriptions, identical or substantially the same as those provided with reference to FIG. 9, are omitted for brevity.

Referring to FIG. 14, unlike the pixel unit PUa described with reference to FIG. 9, a first switch transistor TSW1 of the pixel unit PUb according to an example embodiment may be disposed in a first region R1. A first sub-pixel SPX1 disposed in the first region may include a gate terminal TSW1G of the first switch transistor TSW1. One end of an overflow capacitor CLOFIC may be connected to a contact 200 disposed in the first sub-pixel SPX1. A second floating diffusion region FD2 may be separated into a first partial floating diffusion region FD2-1 and a second partial floating diffusion region FD2-2, which are electrically connected to each other. The first partial floating diffusion region FD2-1 may be disposed in a first region R1, and the second partial floating diffusion region FD2-2 may be disposed in a second region R2.

At least a portion of the doped region DR of the pixel unit PUb according to an example embodiment may overlap a gate terminal VTG of the first transistor TSW1. The gate terminal VTG of the first transistor TSW1 may be electrically connected to a contact CT1. A drain region DRR may be electrically connected to a contact CT2. The contact CT2 may be electrically connected to a power supply voltage node.

A cross-section taken along line A-A′ of the layout of the pixel unit PUb of FIG. 14 may be the same as that of FIG. 10.

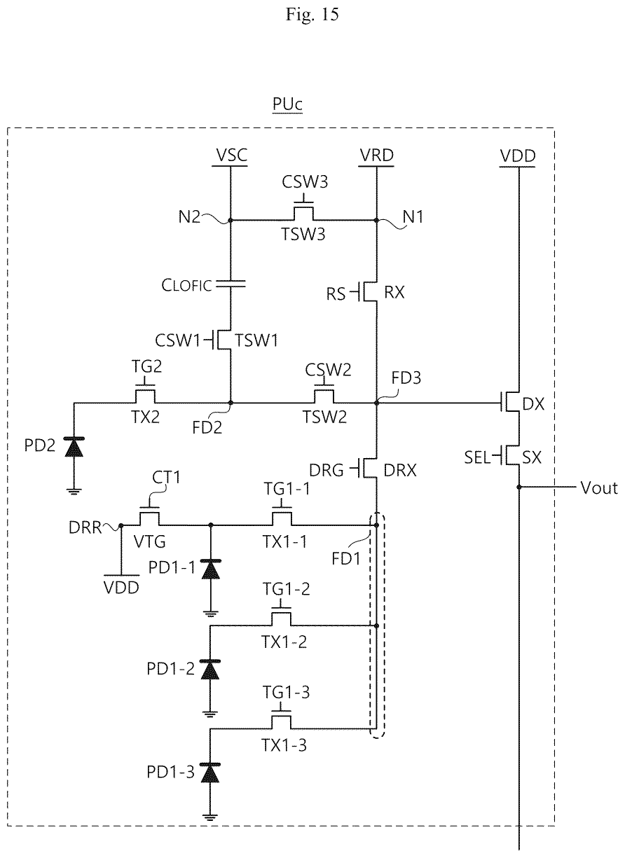

FIG. 15 is a circuit diagram illustrating a pixel unit of an image sensor according to an example embodiment. A pixel unit PUc of FIG. 15 may correspond to the pixel unit PU of FIG. 1. Descriptions, identical or substantially the same as those provided with reference to FIG. 4, are omitted for brevity.

Referring to FIG. 15, unlike the pixel unit PUa of FIG. 4, a first floating diffusion region FD1 of the pixel unit PUc may be shared between a plurality of first photodiodes PD1-1, PD1-2, and PD1-3. For example, the plurality of first photodiodes PD1-1, PD1-2, and PD1-3 may be connected to the first floating diffusion region FD1 through a (1-1)-th transfer transistor TX1-1, a (1-2)-th transfer transistor TX1-2, and a (1-3)-th transfer transistor TX1-3, respectively. The (1-1)-th transfer transistor TX1-1, the (1-2)-th transfer transistor TX1-2, and the (1-3)-th transfer transistor TX1-3 may be controlled by a (1-1)-th transfer transistor control signal TG1-1, a (1-2)-th transfer transistor control signal TG1-2, and a (1-3)-th transfer transistor control signal TG1-3, respectively. The (1-1)-th transfer transistor TX1-1, the (1-2)-th transfer transistor TX1-2, and the (1-3)-th transfer transistor TX1-3 may be turned on at the same time or at different times.

The (1-1)-th transfer transistor TX1-1, the (1-2)-th transfer transistor TX1-2, the (1-3)-th transfer transistor TX1-3, and the second transfer transistor TX2 may be disposed in different regions. The (1-1)-th photodiode PD1-1, the (1-2)-th photodiode PD1-2, the (1-3)-th photodiode PD1-3, and the second photodiode PD2 may be disposed in different regions.

According to an example embodiment, the pixel unit PUc may include a drain region DRR, a first transistor VTG, and a doped region. The drain region DRR, the first transistor VTG, and the doped region may be disposed in the same region as the (1-1)-th photodiode PD1-1 and the (1-1)-th transfer transistor TX1-1. The drain region DRR, the first transistor VTG, and the doped region may not be disposed in a region in which the (1-2)-th photodiode PD1-2, the (1-3)-th photodiode PD1-3, and the second photodiode PD2 are disposed.

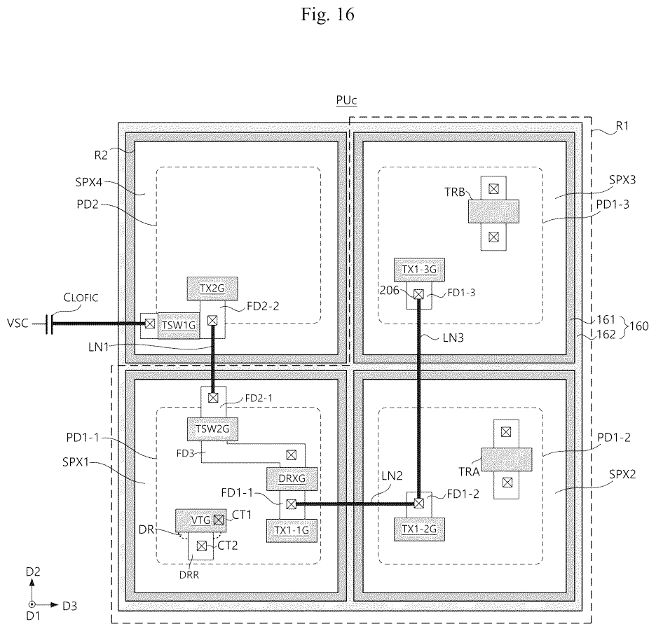

FIG. 16 is a diagram illustrating an example of a pixel unit layout based on the circuit diagram of the pixel unit of FIG. 15. The plan view may be a view from a first direction D1, perpendicular to a substrate. Descriptions, identical or substantially the same as those provided with reference to FIGS. 3, 9, and 14, are omitted for brevity. FIG. 16 illustrates an example of transistors of pixel circuits without specifying the transistors. For example, transistors TRA and TRB may each be one of the transistors of FIG. 15.

Referring to FIG. 16, a (1-1)-th transfer transistor TX1-1, a (1-2)-th transfer transistor TX1-2, a (1-3)-th transfer transistor TX1-3, and ta second transfer transistor TX2 may be disposed in different sub-pixels. A (1-1)-th photodiode PD1-1, a (1-2)-th photodiode PD1-2, a (1-3)-th photodiode PD1-3, and a second photodiode PD2 may be disposed in different sub-pixels. The (1-1)-th transfer transistor TX1-1, the (1-2)-th transfer transistor TX1-2, and the (1-3)-th transfer transistor TX1-3 may be disposed in a first region R1, and the second transfer transistor TX2 may be disposed in a second region R2. The (1-1)-th photodiode PD1-1, the (1-2)-th photodiode PD1-2, and the (1-3)-th photodiode PD1-3 may be disposed in the first region R1, and the second photodiode PD2 may be disposed in the second region R2.

In an example embodiment, the pixel unit PUc may include four sub-pixels SPX1, SPX2, SPX3, and SPX4. Each of the sub-pixels SPX1, SPX2, SPX3, and SPX4 may include a photodiode and a transfer transistor. The sub-pixels SPX1, SPX2, SPX3, and SPX4 may be disposed in different regions.

Areas of the sub-pixels SPX1, SPX2, SPX3, and SPX4 of the pixel unit PUc may be the same. Light receiving areas of the photodiodes PD1-1, PD1-2, PD1-3, and PD2, included in each of the sub-pixels SPX1, SPX2, SPX3, and SPX4, may be the same.

Although FIG. 16 illustrates a pixel unit PUc including four sub-pixels SPX1, SPX2, SPX3, and SPX4, the number of sub-pixels may be greater than four. For example, a pixel unit may include m×n sub-pixels (where m and n are each positive integers greater than 1). Sub-pixels may have the same area. Light receiving areas of photodiodes, included in each of the sub-pixels, may be the same.

In an example embodiment, a portion of the plurality of floating diffusion regions FD1, FD2, and FD3 may be separated and disposed in different regions. The separated floating diffusion regions may be connected to each other by interconnections, and may have the same potential. For example, referring to FIG. 16, the second floating diffusion region FD2 of FIG. 15 may include a first partial floating diffusion region FD2-1, disposed in the first region R1, and a second partial floating diffusion region FD2-2 disposed in the second region R2.

In an example embodiment, a portion of the plurality of floating diffusion regions FD1, FD2, and FD3 may be separated and disposed in different sub-pixels. The separated floating diffusion regions may be connected to each other by interconnections, and may have the same potential.

For example, referring to FIG. 16, the second floating diffusion region FD2 of FIG. 15 may include a first partial floating diffusion region FD2-1, disposed in the first sub-pixel SPX1, and a second partial floating diffusion region FD2-2 disposed in the fourth sub-pixel SPX4. The first partial floating diffusion region FD2-1 and the second partial floating diffusion region FD2-2 may be connected by a first interconnection LN1.

For example, the first floating diffusion region FD1 of FIG. 15 may include a first partial floating diffusion region FD1-1 disposed in the first sub-pixel SPX1, a second partial floating diffusion region FD1-2 disposed in the second sub-pixel SPX2, and a third partial floating diffusion region FD1-3 disposed in the third sub-pixel SPX3. The first partial floating diffusion region FD1-1 and the second partial floating diffusion region FD1-2 may be connected by a second interconnection LN2, and the second partial floating diffusion region FD1-2 and the third partial floating diffusion region FD1-3 may be connected by a third interconnection LN3.

According to an example embodiment, a drain region DRR, a first transistor VTG, and a doped region DR may be disposed in one of the sub-pixels in which a floating diffusion region separated into different regions is disposed. For example, referring to FIG. 16, the first sub-pixel SPX1 may include a drain region DRR, a gate terminal VTG of a first transistor, and a doped region DR. The drain region DRR and the doped region DR may be doped with the same type of dopant as the first photodiode PD1-1. The doped region DR may be doped with a dopant having a lower concentration than that of the first photodiode PD1-1.

The gate terminal VTG of the first transistor may be disposed adjacent to the drain region DRR. The doped region DR may be disposed between the drain region DRR and the first photodiode PD1-1. The gate terminal VTG of the first transistor may receive a control signal through a contact CT1. In an example embodiment, a control signal may always maintain the first transistor in an OFF state. In an example embodiment, the contact CT1 may receive a control signal from a comparator circuit that turns on or off the first transistor.

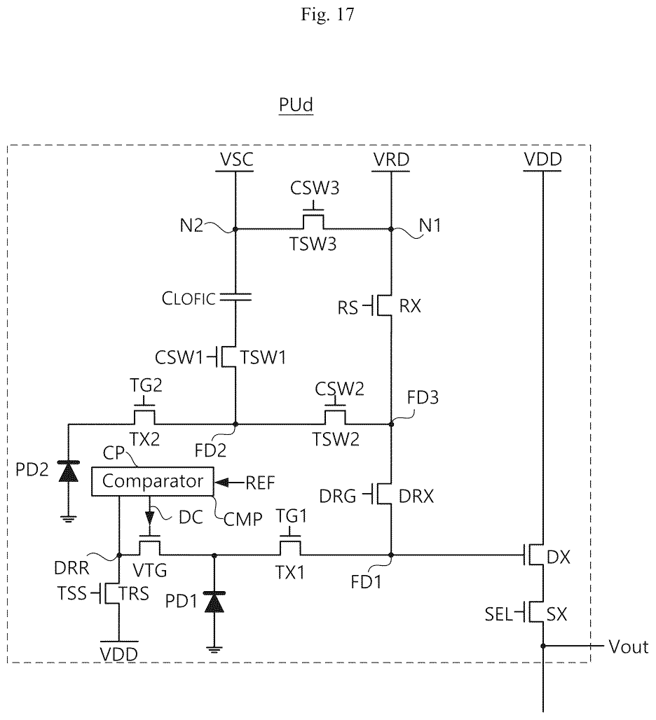

FIG. 17 is a circuit diagram illustrating a pixel unit of an image sensor according to an example embodiment. A pixel unit PUd of FIG. 17 may correspond to the pixel unit PU of FIG. 1. Descriptions, identical or substantially the same as those provided with reference to FIG. 4, are omitted for brevity.

The pixel unit PUd may include at least two sub-pixels. Each of the sub-pixels may include an individual photodiode. For example, the pixel unit PUd may include two sub-pixels, with one sub-pixels including a first photodiode PD1 and the other sub-pixel including a second photodiode PD2. In an example embodiment, the first photodiode PD1 may be a large photodiode LPD having a relatively large light receiving area, and the second photodiode PD2 may be a small photodiode SPD having a relatively small light receiving area.

According to an example embodiment, the sub-pixels of the pixel unit PUd may be separated by a DTI structure. Regions, separated by the DTI structure in the pixel unit PUd, may include a first region and a second region. One of the sub-pixels may be disposed in the first region, and the other sub-pixel may be disposed in the second region. The first region and the second region may be separated from each other by the DTI structure.

In an example embodiment, the second floating diffusion region FD2 may include a first partial floating diffusion region and a second partial floating diffusion region with the DTI structure interposed therebetween. For example, the first partial floating diffusion region may be disposed in the first region, and the second partial floating diffusion region may be disposed in the second region. The first partial floating diffusion region and the second partial floating diffusion region may be electrically connected to each other, and may have the same potential.

The pixel unit PUd may include a drain region DRR, a first transistor VTG, a second transistor TRS, a comparator circuit CP, and a doped region. Unlike the pixel unit PUa described with reference to FIG. 4, the pixel unit PUd according to an example embodiment may include a comparator circuit CP.

The doped region may be disposed between the first photodiode PD1 and the drain region DRR within a substrate.

The drain region DRR may be connected to the first photodiode PD1 with the first transistor VTG interposed therebetween. The drain region DRR may be connected to a power supply voltage node VDD through the second transistor TRS.

In an example embodiment, the first transistor VTG may perform switching between a turn-on operation and a turn-off operation. For example, the first transistor VTG may receive a control signal DC from the comparator circuit CP.

In an example embodiment, the comparator circuit CP may output a control signal based on a result of comparing a voltage of the drain region DRR with a predetermined reference voltage. For example, when the voltage of the drain region DRR reaches a predetermined reference voltage due to overflowed photocharges, the comparator circuit CP may transmit a control signal DC, turning on the first transistor VTG, to the first transistor VTG.

The first transistor VTG may receive a control signal DC at a gate terminal. The first transistor VTG may receive a control signal DC from the comparator circuit CP. In an example embodiment, the control signal DC may switch the first transistor VTG between an OFF state and an ON state.

The comparator circuit CP may receive a reference voltage signal REF and a voltage signal of the drain region DRR. The comparator circuit CP may output a control signal DC based on a result of comparing the voltage signal of the drain region DRR with the reference voltage signal REF. The comparator circuit CP may output a control signal DC based on a result of comparing the magnitudes of the voltage of the drain region DRR and the reference voltage signal REF. For example, photocharges overflowed from the first photodiode PD1 may move to the drain region DRR via the doped region. The comparator circuit CP may monitor the drain region DRR formed by overflowed photocharges and turn on the first transistor VTG when a voltage reaches a voltage of the reference voltage signal REF. Accordingly, the movement of the overflowed photocharges to the drain region DRR may be facilitated.

In an example embodiment, the comparator circuit CP may include an operational transconductance amplifier (OTA)-based comparison circuit. In an example embodiment, the comparator circuit CP may include an inverter-based comparison circuit. The inverter-based comparison circuit may include a smaller number of transistors than an OTA-based comparison circuit. The inverter-based comparison circuit and the OTA-based comparison circuit may be implemented using various circuit configurations known in the art.

The second transistor TRS may be controlled by a control signal TSS. For example, when the voltage of the drain region DRR reaches a specified magnitude due to the overflowed photocharges, the second transistor TRS may be turned on. As a result, the drain region DRR may be reset by a power supply voltage.

Unlike that illustrated in FIG. 17, in an example embodiment, the comparator circuit CP may output a control signal based on a result of comparing a voltage of one of the plurality of floating diffusion regions with a predetermined reference voltage. For example, the comparator circuit CP may be connected to one of the plurality of floating diffusion regions, not to the drain region DRR as in FIG. 17. For example, the comparator circuit may monitor the voltage of the floating diffusion region. When the voltage of the monitored floating diffusion region reaches a predetermined reference voltage due to the overflowed photocharges, the comparator circuit may transmit a control signal, turning on the first transistor, to the first transistor. The monitoring operation of the comparator circuit may be performed during a charge accumulation time. For example, the comparator circuit may perform the monitoring operation of the floating diffusion region during the exposure time of a photodiode.

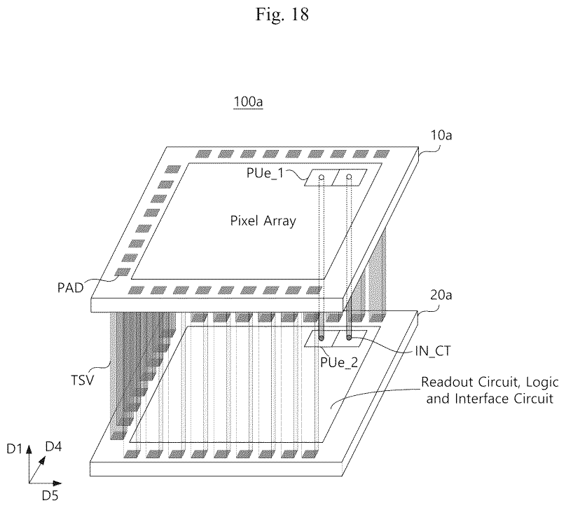

FIG. 18 is a block diagram of an image sensor 100a according to an example embodiment. Descriptions, identical or substantially the same as those provided above, are omitted for brevity.

An image sensor 100a may include a first substrate 10a and a second substrate 20a, which are stacked.

For example, the first substrate 10a may be stacked on a second substrate 20a in a direction D1, perpendicular to a plane of a substrate (a surface parallel to D4 and D5). The first substrate 10a and the second substrate 20a may be electrically connected to each other. For example, the first substrate 10a and the second substrate 20a may transmit pixel signals and/or control signals through a through-silicon via (TSV) disposed in a peripheral circuit region of the substrate. Also, the first substrate 10a and the second substrate 20a may be electrically connected to each other through an in-pixel contact IN_CT inside pixel units PUe_1 and PUe_2. For example, a portion of circuits of the same pixel units PUe_1 and PUe_2 may be disposed in the pixel unit PUe_1 of the first substrate 10a, and another portion of the circuits may be disposed in the pixel unit PUe_2 of the second substrate 20a.

The in-pixel contact may be, for example, a Cu-to-Cu (C2C) bonding contact. A pixel signal of the first substrate 10a may be transmitted to a readout circuit (or an image signal processing logic) of the second substrate 20a.

The second substrate 20a may include at least a portion of a readout circuit, a timing controller, an image signal processing logic, and an interface circuit.

When a pixel unit according to an example embodiment includes a comparator circuit, the comparator circuit may be disposed in the first substrate 10a or the second substrate 20a. The comparator circuit may be disposed in the first substrate 10a or the second substrate 20a based on a size of a sub-pixel of the pixel unit and/or the type of the comparator circuit. For example, when the pixel unit has a tetra sub-pixel structure as in illustrated in the example embodiment of FIG. 16 and the comparator circuit includes an OTA-based comparator circuit, the comparator circuit may be disposed in the second substrate 20a. When the pixel unit has a tetra sub-pixel structure as illustrated in the example embodiment of FIG. 16 and the comparator circuit includes an inverter-based comparator circuit, the comparator circuit may be disposed in the first substrate 10a. Even when the pixel unit has a tetra sub-pixel structure, if a size of the sub-pixel pitch is larger than a specified size, a comparator circuit including an OTA-based comparator circuit may be disposed in the first substrate 10a. This feature is also applicable even when the pixel unit has a split sub-pixel structure of FIGS. 5 to 7.

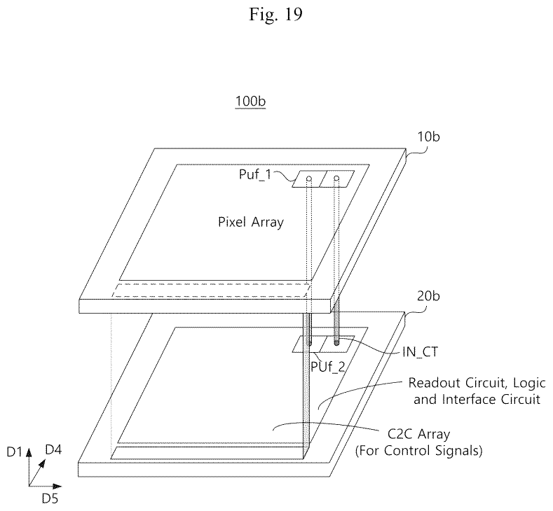

FIG. 19 is a block diagram of an image sensor 100b according to an example embodiment. Descriptions, identical or substantially the same as those provided above, are omitted for brevity.

The image sensor 100b may include a first substrate 10b and a second substrate 20b, which are stacked. The first substrate 10a and the second substrate 20a may be connected to each other through a wafer bonding process using a C2C interconnection at a pixel unit level. The first substrate 10a and the second substrate 20a may be electrically connected not only through an in-pixel contact within pixel units PUf_1 and PUf_2 but also through a Cu-to-Cu (C2C) array disposed in a peripheral circuit region of the substrate. For example, a portion of circuits of the same pixel units PUf_1 and PUf_2 may be disposed in the pixel unit PUf_1 of the first substrate 10b, and another portion of the circuits may be disposed in the pixel unit PUf_2 of the second substrate 20b.

Control signals for controlling the pixel circuit may be transmitted through the C2C array. A pixel signal of the first substrate 10b may be transmitted to a readout circuit (or an image signal processing logic) of the second substrate 20b through an in-pixel contact.

When the pixel unit according to an example embodiment includes a comparator circuit, the comparator circuit may be disposed in the first substrate 10b or the second substrate 20b. The comparator circuit may be disposed in the first substrate 10b or the second substrate 20b based on a size of a sub-pixel of the pixel unit and/or the type of the comparator circuit.

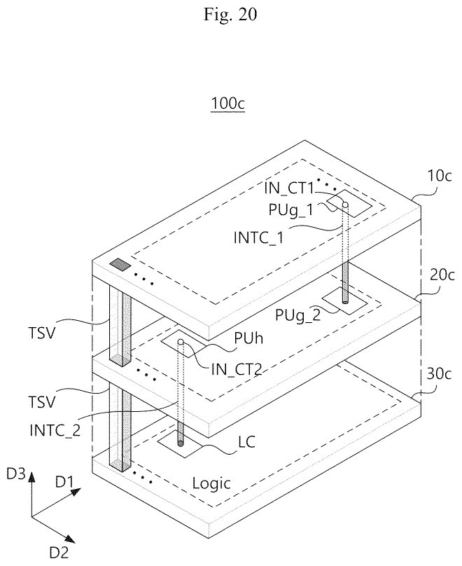

FIG. 20 is a block diagram of an image sensor 100c according to an embodiment of the present application. Descriptions, identical or substantially the same as those provided above, are omitted for brevity.

Referring to FIG. 20, the image sensor 100c may include a first substrate 10c, a second substrate 20c, and a third substrate 30c. The third substrate 30c, the second substrate 20c, and the first substrate 10c may be sequentially disposed in a direction D3, perpendicular to a plane of a substrate (a surface parallel to D1 and D2).

In an example embodiment, a portion of circuits of the pixel units PUg_1 and PUg_2 may be formed on each of the first substrate 10c and the second substrate 20c. The first part circuit PUg_1 of the pixel units PUg_1 and PUg_2 may be disposed on the first substrate 10c, and the remaining second part circuit PUg_2 of the pixel units PUg_1 and PUg_2 may be disposed on the second substrate 20c. The third substrate 30c may include a readout circuit, a timing controller, an image signal processing logic, and an interface circuit. The readout circuit may include an ADC.

The first substrate 10c and the second substrate 20c may be electrically connected to each other.

In an example embodiment, the first substrate 10c and the second substrate 20c may transmit a pixel signal or a control signal through a through-silicon via TSV disposed in the peripheral circuit region of the substrate.

In an example embodiment, the first part circuit PUg_1 of the same pixel units PUg_1 and PUg_2 of the first substrate 10c and the second part circuit PUg_2 of the second substrate 20c may also be electrically connected through a first inter-substrate connection structure IN_CT1. The first inter-substrate connection structure IN_CT1 may be a Cu-to-Cu (C2C) bonding contact or a deep-contact structure. The deep-contact structure may include a through-silicon via.

In an example embodiment, the first substrate 10c and/or the second substrate 20c may be electrically connected to the third substrate 30c through a through-silicon via TSV and/or a second inter-substrate connection structure IN_CT2. Signals of the first substrate 10c and/or the second substrate 20c may be transmitted to the readout circuit (or the image signal processing logic) of the third substrate 30c through the through-silicon via TSV and/or the second inter-substrate connection structure IN_CT2.

In an example embodiment, the second part circuit PUg_2 of the pixel units PUg_1 and PUg_2 may be electrically connected to the circuits of the third substrate 30c through the Cu-to-Cu (C2C) bonding contact. The second inter-substrate connection structure IN_CT2 may include a Cu-to-Cu (C2C) bonding contact.

In an example embodiment, the second part circuit PUg_2 of the pixel units PUg_1 and PUg_2 may be electrically connected to the circuits of the third substrate 30c through through-silicon copper TSC.

When the pixel unit according to an example embodiment includes a comparator circuit, the comparator circuit may be disposed in the first substrate 10b or the second substrate 20b. The comparator circuit may be disposed in the first substrate 10b or the second substrate 20b based on a size of the sub-pixel of the pixel unit and/or the type of the comparator circuit.

As set forth above, according to example embodiments, an image sensor may mitigate blooming caused by the movement of photocharges through an unintended path.

While example embodiments have been shown and described above, it will be apparent to those skilled in the art that modifications and variations could be made without departing from the scope of the present inventive concept as defined by the appended claims.

What is claimed is:

1. An image sensor comprising:
a first photodiode disposed in a first region of a pixel unit and a second photodiode disposed in a second region of the pixel unit;
a deep trench isolation (DTI) structure disposed between the first photodiode and the second photodiode;
a plurality of floating diffusion regions configured to store charges transferred from at least one of the first photodiode and the second photodiode;
a lateral overflow integration capacitor configured to store charges overflowed from the second photodiode;
a drain region connected to a power supply voltage node and disposed in the first region;
a first transistor disposed in the first region and adjacent to the drain region; and
a first doped region disposed between the first photodiode and the drain region and doped with an N-type dopant,
wherein one of the plurality of floating diffusion regions comprises partial floating diffusion regions, and
wherein the partial floating diffusion regions are electrically connected to each other with the DTI structure interposed therebetween, and are disposed in the first region and the second region, respectively.

2. The image sensor of claim 1, comprising:
a first transfer transistor connecting the first photodiode and a first floating diffusion region among the plurality of floating diffusion regions;
a second transfer transistor connecting the second photodiode and a second floating diffusion region among the plurality of floating diffusion regions; and
a third floating diffusion region connected to each of the first and second floating diffusion regions through at least one transistor.

3. The image sensor of claim 2,
wherein the second floating diffusion region comprises the partial floating diffusion regions, and
wherein the first floating diffusion region is disposed in the first region.

4. The image sensor of claim 1,
wherein the first transistor is maintained in an OFF state while the first photodiode accumulates charges.

5. The image sensor of claim 1, further comprising:
a second transistor between the drain region and the power supply voltage node; and
a comparator circuit configured to transmit a control signal to a gate terminal of the first transistor based on a result of comparing a voltage of the drain region with a reference voltage.

6. The image sensor of claim 5, comprising:
a plurality of substrates electrically connected to each other and vertically stacked,
wherein the pixel unit is disposed on a first substrate among the plurality of substrates, and
wherein at least a portion of the comparator circuit is disposed on a substrate, other than the first substrate, among the plurality of substrates.

7. The image sensor of claim 5, comprising:
a plurality of substrates electrically connected to each other and vertically stacked,
wherein the pixel unit is disposed on a first substrate among the plurality of substrates; and
wherein at least a portion of the comparator circuit is disposed on the first substrate among the plurality of substrates.

8. The image sensor of claim 1,
wherein the first photodiode has a larger light-receiving area than the second photodiode.

9. The image sensor of claim 1,
wherein the first doped region has a lower doping concentration than the first photodiode.

10. The image sensor of claim 1,
wherein the first doped region is spaced apart from a plane of a substrate by a predetermined depth in a vertical direction.

11. The image sensor of claim 10,
wherein the first doped region is spaced apart from the first photodiode in a direction perpendicular to the plane of the substrate.

12. The image sensor of claim 10,
wherein the first doped region is disposed between the first photodiode and the drain region,
wherein the first transistor comprises a vertical gate, and
wherein at least a portion of the first doped region overlaps the vertical gate of the first transistor when viewed in a direction perpendicular to the plane of the substrate.

13. The image sensor of claim 12,
wherein the first doped region does not overlap the drain region when viewed in the direction perpendicular to the plane of the substrate.

14. The image sensor of claim 1, comprising:
an interconnection electrically connecting the partial floating diffusion regions to each other.

15. The image sensor of claim 1,
wherein the first doped region is configured to provide a path through which photocharges, overflowed from the first photodiode, move to the drain region.

16. The image sensor of claim 1, further comprising:
a shallow trench isolation (STI) structure connected to the DTI structure.

17. An image sensor comprising:
a pixel array comprising a plurality of pixel units; and
a readout circuit configured to receive a pixel signal from each of the plurality of pixel units,
wherein each of the plurality of pixel units comprises a plurality of sub-pixels separated by a deep trench isolation (DTI) structure, a plurality of floating diffusion regions, and a lateral overflow integration capacitor in which overflowed charges are accumulated,
wherein each of the plurality of sub-pixels comprises a photodiode,
wherein one of the plurality of floating diffusion regions comprises partial floating diffusion regions disposed in at least two sub-pixels among the plurality of sub-pixels, and the partial floating diffusion regions have the same potential, and
wherein one of the plurality of sub-pixels comprises:
a drain region connected to a power supply voltage node;
a first transistor adjacent to the drain region; and
a doped region disposed between the photodiode and the drain region within a substrate and doped with an N-type dopant.

18. The image sensor of claim 17,
wherein each of the plurality of sub-pixels comprises one of a first photodiode and a second photodiode,
wherein the plurality of floating diffusion regions comprise:
a first floating diffusion region connected to the first photodiode through a first transfer transistor;
a second floating diffusion region connected to the second photodiode through a second transfer transistor; and
a third floating diffusion region connected to the first and second floating diffusion regions through a second transistor and a third transistor, respectively, and
wherein one of the second and third floating diffusion regions comprises the partial floating diffusion regions.

19. The image sensor of claim 17,
wherein the doped region and the drain region are disposed in a sub-pixel in which one of the partial floating diffusion regions is disposed.

20. An image sensor comprising:
a first region in which a first photodiode having a first area is disposed;
a second region in which a second photodiode having a second area, smaller than the first area, is disposed;
a deep trench isolation (DTI) structure separating the first region and the second region;
a first floating diffusion region connected to the first photodiode through a first transfer transistor;
a second floating diffusion region connected to the second photodiode through a second transfer transistor;
a third floating diffusion region selectively electrically coupled to at least one of the first and second floating diffusion regions;
a lateral overflow integration capacitor in which charges, overflowed from the second photodiode, are accumulated;
a drain region connected to a power supply voltage node and disposed in the first region;
a first transistor disposed in the first region and adjacent to the drain region; and
a doped region disposed between the first photodiode and the drain region within a substrate and doped with an N-type dopant,
wherein one of the first, second, and third floating diffusion regions comprises partial floating diffusion regions, respectively disposed in the first region and the second region, and the partial floating diffusion regions have the same potential.
